(19) United States
(12) Patent Application Publication
(10) Pub. No.: US 2018/0306874 A1
(43) Pub. Date: Oct. 25, 2018

(54) CONSTRUCTING A MAP OF A MULTIDIMENSIONAL FIELD USING MEASUREMENT DATA FROM ONE DIMENSION OF THE FIELD

(71) Applicant: University of Florida Research Foundation, Inc., Gainesville, FL (US)

(72) Inventors: NICOLAS GARRAUD, GAINESVILLE, FL (US); WILLIAM C. PATTERSON, Gainesville, FL (US); DAVID P. ARNOLD, GAINESVILLE, FL (US)

(21) Appl. No.: 16/068,228

(22) PCT Filed: Jan. 6, 2017
(86) PCT No.: PCT/US2017/012446

§ 371 Date: Jul. 5, 2018

Related U.S. Application Data
(60) Provisional application No. 62/275,922, filed on Jan. 7, 2016.

(51) Int. Cl. G01R 33/05; G01R 33/032; G06F 17/16; G06F 17/14

(52) U.S. Cl. CPC G01R 33/05; G06F 17/147; G06F 17/16; G01R 33/032

(57) ABSTRACT

An exemplary system for determining field characteristics using one dimension of a vector field utilizes a field measurement apparatus configured to acquire measurement data of the vector field corresponding to one dimension of the vector field and at least one computing device configured to simultaneously solve a set of equations characterizing the vector field by composing the set of equations into discrete counterparts, obtaining the measurement data of the vector field as input data for the discrete counterparts to the set of equations, and computing output data satisfying the discrete counterparts to the set of equations in at least one vector dimension that differs from the vector dimension of the input data using a matrices solution.

### CROSS-REFERENCE TO RELATED APPLICATION

This application claims priority to co-pending U.S. provisional application entitled, “Constructing Maps of Multidimensional Fields using Data for One Dimension of the Field,” having Ser. No. 62/275,922, filed Jan. 7, 2016, which is entirely incorporated herein by reference.

### TECHNICAL FIELD

The present disclosure is generally related to a determination of multidimensional field characteristics using a single dimensional field information.

### BACKGROUND

The ability to measure and map vector fields, such as a magnetic vector field, is important for research, production, quality control, and process troubleshooting. Direct measurement of all three axes of the vector field is difficult for small-scale devices and is generally slow since the number of acquisition points is large. In addition, existing methods of reconstruction for the full three-dimensional (3D) field are very sensitive to errors (noise and defects) in the initial measurements, which makes current reconstruction methods inaccurate or impossible.

### SUMMARY

Embodiments of the present disclosure provide systems and methods, among others, for determining field characteristics using one dimension of a vector field. Briefly described, in architecture, one embodiment of the system, among others, can be implemented as follows. Such a system comprises a field measurement apparatus configured to acquire measurement data of the vector field corresponding to one dimension of the vector field. The system further comprises at least one computing device having a processor and memory, in which the at least one computing device is configured to simultaneously solve a set of equations characterizing the vector field by composing the set of equations into discrete counterparts, obtaining the measurement data of the vector field as input data for the discrete counterparts to the set of equations, and computing output data satisfying the discrete counterparts to the set of equations in at least one vector dimension that differs from the vector dimension of the input data using a matrices solution

In certain embodiments, the system is further defined by the vector field comprising a magnetic field; the field measurement apparatus comprising a magneto-optical indicator film (MOIF); the vector field comprising a fluidic flow field; the vector field comprising an electric field; the vector field (\vec{A}) satisfying ∇·\vec{A}=0 and ∇×\vec{A}=0 for at least a set condition; and/or a mapping module configured to construct a three dimensional map of the vector field from the measurement data and the output data, among other possible features.

The present disclosure can also be viewed as providing methods for determining field characteristics using one dimension of a vector field. In this regard, one embodiment of such a method, among others, can be broadly summarized by the following steps: obtaining, by at least one computing device, a set of equations for a multidimensional vector field; obtaining, by the at least one computing device, measurement data for one dimension of the vector field; calculating, by the at least one computing device, output data along the remaining dimensions of the vector field by simultaneously solving the set of equations using the measurement data; and constructing, by the at least one computing device, a three-dimensional model of the multidimensional vector field from the measurement data and the output data.

In certain embodiments, the method is further defined by the following features and/or steps: the measurement data is acquired from a magneto-optical indicator film (MOIF); the measurement data comprises a plurality of slices along increasing heights of a single component of the vector field; the vector field comprises a magnetic field; the vector field comprises a fluidic flow field; the vector field (\vec{A}) satisfies ∇·\vec{A}=0 and ∇×\vec{A}=0 for at least a set condition; and/or positively validating a theoretical model of the vector field against the constructed model of the vector field without applying an error correction process to the constructed model.

The present disclosure can also be viewed as providing a computer readable medium having a computer program for determining field characteristics using one dimension of a vector field. In this regard, one embodiment of such a computer readable medium, among others, includes computer instructions that, when executed, cause a computing device to at least: obtain measurement data for one dimension of the vector field; calculate output data corresponding to the remaining dimensions of the vector field by simultaneously solving the set of equations using the measurement data; and/or construct a three-dimensional map of the multidimensional vector field from the measurement data and the output data.

Other systems, methods, features, and advantages of the present disclosure will be or become apparent to one with skill in the art upon examination of the following drawings and detailed description. It is intended that all such additional systems, methods, features, and advantages be included within this description, be within the scope of the present disclosure, and be protected by the accompanying claims.

### BRIEF DESCRIPTION OF THE DRAWINGS

Many aspects of the present disclosure can be better understood with reference to the following drawings. The components in the drawings are not necessarily to scale, emphasis instead being placed upon clearly illustrating the principles of the present disclosure. Moreover, in the drawings, like reference numerals designate corresponding parts throughout the several views.

FIG. 1 is a block diagram of an improved vector field mapping system in accordance with an embodiment of the present disclosure.

FIG. 2 is a diagram showing a plot of data values along respective axes for a reconstructed 3D model of a magnetic field using a conventional methodology.

FIG. 3 is a diagram showing a plot of data values along respective axes for a reconstructed 3D model of a magnetic field using the improved vector field mapping system of FIG. 1.

FIG. 4 is a flowchart diagram showing an exemplary method for determining field characteristics using one dimension of a vector field in accordance with the present disclosure.

FIG. 5 is a block diagram showing a computing device that can implement functionality of the flowchart of FIG. 4 in accordance with an embodiment of the present disclosure.

### DETAILED DESCRIPTION

Embodiments of the present disclosure include a method and system of producing a multidimensional (e.g., 3D) map of a vector field from measurements along a unitary axis of the vector field. In one embodiment, the vector field being measured comprises, but is not limited to, a magnetic field. Accordingly, in one application, stray magnetic fields from microscale devices, such as magnetic actuators, magnetic microsystems, hard disk read/write heads, magnetic memory, magnetometers, integrated circuits, and other microelectronic devices, can be measured and mapped. The ability to measure and map the fields from these types of devices is important for research, production, quality control, and process troubleshooting. Direct measurement of all three axes of the magnetic vector field (B-field) is very difficult for these small-scale devices. Embodiments of the present disclosure thereby improves 3D map processing of vector fields by acquiring measurements of the vector field along a unitary axis and reconstructing the full 3D field using novel signal processing, as described below, that provides maps having improved quality (e.g., more accurate and less noisy). As a result, an error correction stage or circuitry is not necessary to be integrated as part of an overall system or process and can be skipped, thereby improving and simplifying the resulting system/process. Accordingly, a theoretical model of the vector field can be positively validated against the constructed model of the vector field without applying an error correction process to the constructed model.

For example, for a vector field \vec{A} having x, y, and z components, i.e. \vec{A}(x,y,z)=Aₓ(x,y,z)\hat{x}+A_{y}(x,y,z)ŷ+A_{z}(x,y,z)\hat{z}, the x and y components of the field can be constructed using measurements of only the z component of the field. The approach can also be applied to other coordinate systems such as spherical or cylindrical coordinate systems. The techniques described herein can be used to generate a map for a multidimensional vector field \vec{A} for which ∇·\vec{A}=0 and ∇×\vec{A}=0. In the case of a magnetic field \vec{B}, it is known that ∇·\vec{B}=0 and ∇×\vec{B}=0 in the absence of an electric field. These mathematical conditions can model physical systems, for example electromagnetics and fluid dynamics. Accordingly, for other types of fields besides magnetic fields (e.g., fluidic flow fields, electric fields, among others), ∇·\vec{A}=0 and ∇×\vec{A}=0, may be satisfied for a range or defined set of conditions. In such a scenario, a 3D map of the vector field can be constructed using the systems and methods of the present disclosure.

The systems and methods described here are particularly useful when direct measurement of three-dimensional vector quantities are experimentally difficult, costly, or time-consuming. One example may relate to measurements of field quantities at small dimensional scales, such as millimeter or micrometer length scales. As small size scale, a vector sensor technology may not provide sufficient spatial resolution for resolving the vector field at a locality in space. A second example may relate to experimental measurement techniques where a high spatial density of experimental measurements may be obtained in a geometric plane.

To construct the map of a field having x, y, and z components, the z component of the field can be measured at various points in space. In one example, a magneto-optical indicator film (MOIF) can be used to determine the z component of the stray magnetic field produced by a magnetic structure. In another example, hot wire anemometry or particle image velocimetry may be used to determine the z component of fluidic flow fields. Other types of sensors and measurement tools may also be used to acquire measurement data in certain embodiments.

Once the z component of the field has been measured at various points in space, a set of equations can be constructed from the initial starting point: ∇·\vec{A}=0 and ∇×\vec{A}=0. These equations can then be solved simultaneously using various methods, such as a least means squares algorithm, as understood by one of ordinary skill in the art. Solving the simultaneous equations may then result in the x and y components of the field being determined, and a map of the field being constructed based on this information.

The usage of simultaneous equations to determine the x and y components of the field can provide benefits over other techniques. For example, attempts to construct the x and y components of a field at some points in space by solving decoupled independent equations (as utilized in conventional methods via brute force techniques) when using information from only the z component of the field may produce unrealistic or inaccurate results. These unrealistic results may arise due to noise, experimental uncertainties, or insufficient spatial density in the z component data. However, by creating and solving simultaneous equations, as described herein, the x and y components of the field can be constructed for all points in space by forcing the results to converge according to the mathematical assumptions of ∇·\vec{A}=0 and ∇×\vec{A}=0 (which can model certain laws of physics) using information from only the z component of the field. In various embodiments, a different unitary axis (e.g., x-axis component of the vector field) may be selected to be used in acquiring field measurement data in accordance with the present disclosure.

The functionality described herein is performed by one or more computing devices/systems in order to carry out the complex mathematical processing of the resulting equations. As such, computer instructions can be stored in memory and be executable by one or more processors in the computing device. Upon execution, the computer instructions can cause the one or more processors to perform the functionality described herein.

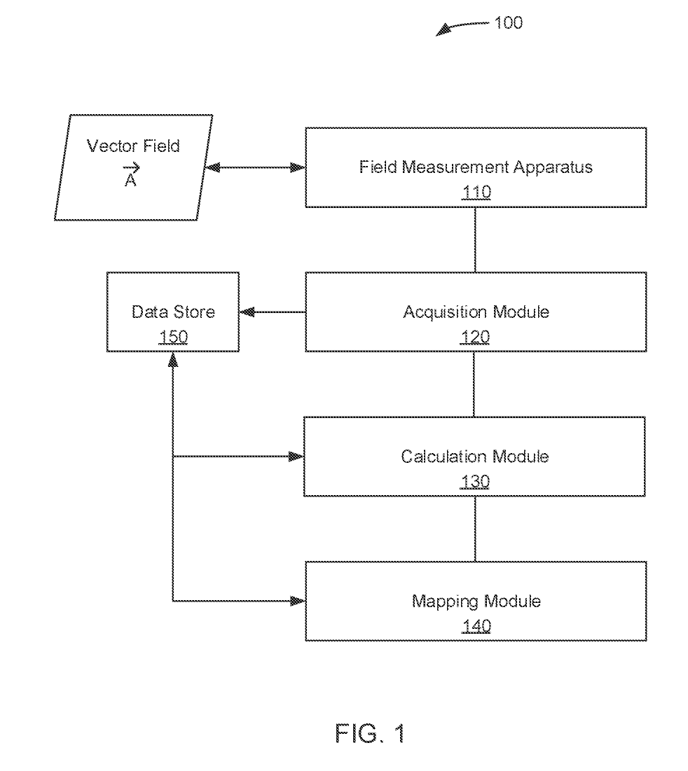

For example, FIG. 1 illustrates an improved vector field mapping system 100 in accordance with an embodiment of the present disclosure. The system 100 includes a field measurement apparatus 110, acquisition module 120, a calculation module 130, and a mapping module 140. The field measurement apparatus 110 measures data from a vector field at various points in space along a single dimension of the respective field. Various types of measurement tools or sensors may be used as measurement apparatuses with embodiments of the present disclosure. In one example, a magneto-optical indicator film (MOIF) can be used to determine the z component of the stray magnetic field produced by a magnetic structure.

The acquisition module 120 receives measurement inputs from the measurement apparatus 110. Accordingly, in various embodiments, the acquisition module 120 may be a computer system or a component of a computer system that is configured to store the measurement data obtained from the measurement apparatus 110.

The calculation module 130 calculates vector field characteristics corresponding to points in the vector field that have not been measured by the measurement, such as those corresponding to field dimensions that are not being measured by the measurement apparatus. For example, the calculation module 130 may utilize measurements along a z-dimension of a particular vector field to output x and y dimensions of the vector field via simultaneous processing of equations characterizing properties of the vector field. Accordingly, in various embodiments, the calculation module 130 is configured to access a data store 150 of a set of equations characterizing the vector field along a set of dimensions, solve the set of equations simultaneously using the acquired data corresponding to one of the dimensions from the measurement apparatus, and output data points of the vector field corresponding to the multiple dimensions of the vector field in the data store 150. Correspondingly, the mapping module 140 is configured to map a multidimensional vector field using the data points in the data store 150.

By limiting the amount of measurements needed to be acquired by the field measurement apparatus 110 to one dimension of the vector field, the amount of noise or defects present in such measurements and possibly passed to the calculation module 130 is also limited. With improved vector maps, simulated models of the vector fields can be mapped and compared with the vector field maps produced from the measurements in the field/lab to verify/test the respective model with real world data.

Whereas existing methods of reconstruction for the full 3D field are very sensitive to errors (noise and defects) in the initial measurements in conventional systems, which makes them inaccurate or impossible, embodiments of the present disclosure can produce accurate and noise-free 3D vector field maps, even using noisy initial measurements along a unitary axis. The signal processing method may also have application to measurement of a variety of vector fields (for example, magnetic fields and fluid mechanics under certain flow conditions).

As a non-limiting illustration, an exemplary 3D construction of a map for a magnetic field is now discussed. Here, magnetic field imaging using a field measurement apparatus 110 can be performed. In one embodiment, the field measurement apparatus 110 is an upright reflective polarizing light microscope outfitted with specialized magnetic field indicator films. Via the field measurement apparatus 110, measurement “slices” are made at increasing heights, and each slice is only sensitive to a single component of the magnetic field (out of plane or z-axis). The calculating module 130 is then configured to reconstruct the other B-field components (in-plane or x and y axis) using the signal processing techniques of the present disclosure.

For example, the Maxwell equations in the absence of an electric field are as follows, where B represents the magnetic field.

∇·\vec{B}=0

∇×\vec{B}=0

In Cartesian coordinates, the foregoing equations can be broken down as following 4 equations.

∇·\vec{B}=dBₓ/dx+dB_{y}/dy+dB_{z}/dz=0

dB_{y}/dz=dB_{z}/dy

dBₓ/dz=dB_{z}/dx

dB_{y}/dx=dBₓ/dy

For reference, B_{y} and Bₓ can be solved independently using brute force from measured data points of B_{z} based on the following.

$${dB}_{y} / dz = {dB}_{z} / dy \to {\vec{B}}_{y} = {\int }_{{z}_{1}}^{∞} \frac{\partial {B}_{z}}{\partial y} dz \approx \sum \frac{\partial {B}_{z}}{\partial y}$$

$${dB}_{x} / dz = {dB}_{z} / dx \to {\vec{B}}_{x} = {\int }_{{z}_{1}}^{∞} \frac{\partial {B}_{z}}{\partial x} dz \approx \sum \frac{\partial {B}_{z}}{\partial x}$$

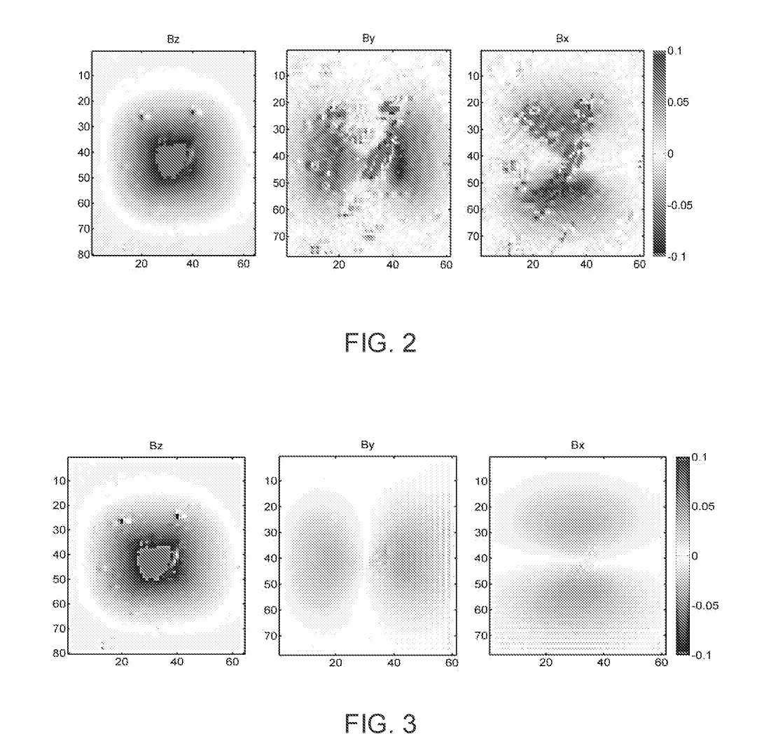

However, solving the equations independently may introduce noise and inaccuracies in the resulting numbers. For example, FIG. 2 shows a plot of data values along respective axes for a reconstructed 3D model of the magnetic field using a brute force methodology for Bₓ and B_{y}, where B_{z} contains the measured values. As depicted, the 3D models contain a large amount of noise and also contains significant areas without data values for the reconstructed Bₓ and B_{y} models. Next, a different manner for reconstructing the 3D models using a set of simultaneous equations (rather than decoupled independent equations) is explained for an exemplary embodiment of the present disclosure. For example, by solving decoupled independent equations using conventional techniques, the results are less constrained by realistic physics, but still solvable at all points in space. A simultaneous solution, however, forces the results to converge toward obeying the laws of physics more closely as defined by the equations.

Accordingly, in one exemplary embodiment of the present disclosure, the Maxwell equations may be composed as discrete counterparts making them suitable for numerical evaluation on a computer system. For example, after discretization, the following 4 discrete equations can be derived from the Maxwell equations for the magnetic field as follows for the Cartesian coordinate system.

Between 3 pixels:

$$\frac{\partial {B}_{x} ( i , j , k )}{\partial y} \approx \frac{{B}_{x} ( i , j + 1 , k ) - {B}_{x} ( i , j - 1 , k )}{2 Δ y}$$

By substitution, the 4 equations can now be composed as the following linear equations:

$${B}_{y} ( i , j , k + 1 ) - {B}_{y} ( i , j , k - 1 ) = \frac{2 Δ xy}{Δ {z}_{1} + Δ {z}_{2}} ( {B}_{z} ( i , j + 1 , k ) - {B}_{z} ( i , j - 1 , k ) )$$

$${B}_{x} ( i , j , k + 1 ) - {B}_{x} ( i , j , k - 1 ) = \frac{2 Δ xy}{Δ {z}_{1} + Δ {z}_{2}} ( {B}_{z} ( i + 1 , j , k ) - {B}_{z} ( i - 1 , j , k ) )$$

$${B}_{x} ( i , j + 1 , k ) - {B}_{x} ( i , j - 1 , k ) + {B}_{y} ( i + 1 , j , k ) - {B}_{y} ( i - 1 , j , k ) = 0$$

$$\frac{{B}_{x} ( i + 1 , j , k ) - {B}_{x} ( i - 1 , j , k )}{2 Δ xy} + \frac{{B}_{y} ( i , j + 1 , k ) - {B}_{y} ( i , j - 1 , k )}{2 Δ xy} = - \frac{{B}_{z} ( i , j , k + 1 ) - {B}_{z} ( i , j , k - 1 )}{Δ {z}_{1} + Δ {z}_{2}}$$

Using computer processing and the B_{z} values obtained from the field measurement apparatus 110, the equations can then be solved simultaneously via various matrices solutions known to one of ordinary skill in the art (e.g., by calculation module 130), such as a least-square-means solution or technique, inverse matrices, among others. This novel field reconstruction method can be applied to magnetic field data collected using other methods (other than magneto optical imaging) and can be applied to field data for other vector fields. Referring to FIG. 3, the reconstructed 3D model of the magnetic field using the exemplary methodology of the present disclosure (e.g., as performed by mapping module 140) is shown for Bₓ and B_{y}, where B_{z} contains the measured values. As depicted, the 3D models contain significantly less noise and also contains significantly fewer areas without data values for the reconstructed Bₓ and B_{y} models as compared to FIG. 2. In general, the curves represented in FIG. 3 are smoother and more continuous than those represented in FIG. 2. Such plots, as demonstrated by FIG. 3, can be used to positively validate a theoretical model of the vector field against a constructed model of the vector field without applying an error correction process to the constructed model, in accordance with certain embodiments of the present disclosure. Further, with respect to FIGS. 2-3, although the respective figures are not capable of being represented in a color format for the present application, it is noted that the original plots depicted positive and negative values in different colors that are not currently represented in the black/white format.

Referring back to the field measurement and mapping components of the vector field mapping system 100, there are two common approaches for mapping of magnetic fields in two or three spatial dimensions: raster scanning a single-point sensor or using optical based methods to measure the fields from a 2D imaging plane. Accordingly, in various embodiments, the field measurement apparatus 110 can acquire the measurement data by scanning one or more field sensors, obtaining the data from an array of field sensors, or obtaining an optical image that is correlated with the vector field, among other techniques. The magnetic structure size and smallest field feature determine the necessary spatial resolution of the measurement approach. The area and/or volume of the desired field map and acceptable data collection time can also be limiting factors for choosing a field measurement technique.

Approaches such as magnetic force microscopy (MFM) and scanning Hall probe microscopy (SHPM) satisfy the necessary spatial resolution and field amplitude range requirements, and can be used by field measurement apparatuses 110 in some embodiments. Alternatively, magneto-optical imaging (MOI) is an optical-based technique that can be used by field measurement apparatuses 110 in certain embodiments, such as in the mapping of fields from magnetic microsystems.

Such a measurement tool for MOI is a magneto-optical indicator film (MOIF) assisted magneto-optical microscope (MOM) for quantitative imaging and measurement of stray magnetic fields produced from micromagnetic structures. Benefits of this type of measurement system include high magnetic field resolution (ranging ±50 μT to ±1 mT), fast characterization (few seconds) over a large spatial area (˜cm2), with a high spatial resolution (ranging 4-20 μm), and being non-destructive, non-invasive, noncontact, and relatively inexpensive total hardware cost (˜20 k).

The MOIF operates by leveraging the Faraday effect for optical measurement of magnetic fields. In particular, the MOIF is a multi-layer sensor that includes: an optically transparent substrate layer that provides mechanical support and the correct crystal structure for film growth, a MOL causing the Faraday effect, an opaque mirror coating to reflect the light back through the MOL again, and a protective layer made of a high-hardness material to protect the mirror and MOL. Additional information on the origin and capabilities of the MOIF is available in a publication titled “A Magneto-Optical Microscope for Quantitative Measurement of Magnetic Microstructures,” by W. C. Patterson, N. Garraud, E. E. Shorman, and D. P. Arnold, published on September, 2015, which is incorporated herein in its entirety. Accordingly, one embodiment of a field measurement apparatus 110 comprises a magneto-optical indicator film (MOIF) assisted magneto-optical microscope.

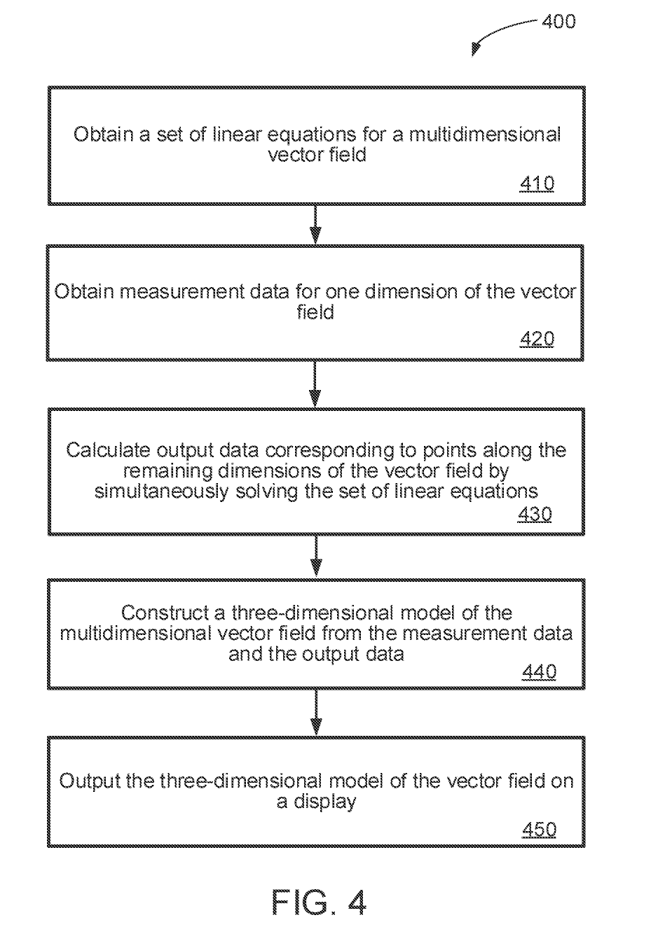

Next, the flow chart of FIG. 4 shows an exemplary method for determining field characteristics using one dimension of a vector field in accordance with embodiments of the present disclosure. The method 400 of FIG. 4 comprises obtaining (410) a set of equations for a multidimensional vector field. As an example, the equations may comprise Maxwell equations characterizing a magnetic field in the absence of an electric field, among others. Further, a computing device may obtain the equations from a computing data store 150 and/or memory. The computing device (or an acquisition module 120 of the same or a different computing device) may then obtain (420) measurement data for one dimension of the vector field. The measurement data may be acquired directly from a field measurement apparatus or tool 110 or maybe acquired from a computer data store 150 or repository for the field measurement data. Using the measurement data, the computing device (or a calculation module 130 of the same or a different computing device) calculates (430) output data corresponding to points along remaining dimensions of the vector field by simultaneously solving the set of equations. Then, the computing device (or a mapping module 140 of the same or a different computing device), can construct (440) a three-dimensional model of the multidimensional vector field from the measurement data and the output data. Further, the computing device can output (450) or present the three-dimensional model of the vector field on a display.

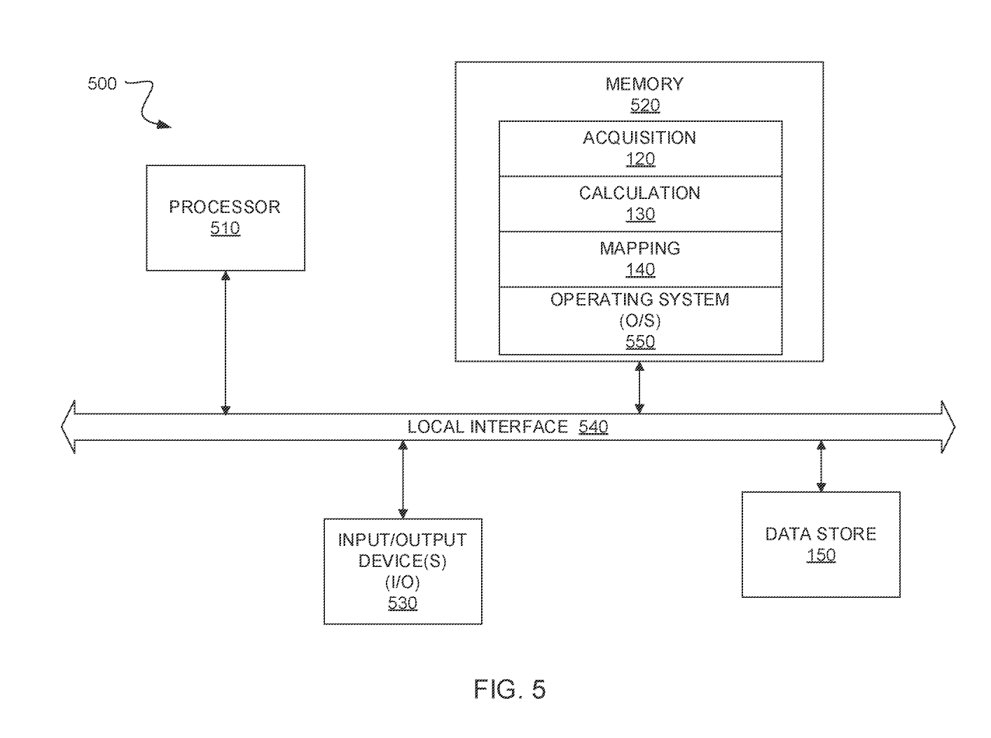

The acquisition module 120, the calculation module 130, and/or the mapping module 140 can be implemented in software (e.g., firmware), hardware, or a combination thereof. For example, in an exemplary mode, the calculation module 130, among others, is implemented in software, as an executable program, and is executed by a special or general purpose digital computer. An example of a computer that can implement the calculation module 130 of the present disclosure is shown in FIG. 5.

Generally, in terms of hardware architecture, as shown in FIG. 5, the computer 500 includes a processor 510, memory 520, and one or more input and/or output (I/O) devices 530 (or peripherals) that are communicatively coupled via a local interface 540. The local interface 540 can be, for example but not limited to, one or more buses or other wired or wireless connections, as is known in the art. The local interface 540 may have additional elements, which are omitted for simplicity, such as controllers, buffers (caches), drivers, repeaters, and receivers, to enable communications. Further, the local interface may include address, control, and/or data connections to enable appropriate communications among the aforementioned components.

The processor 510 is a hardware device for executing software, particularly that stored in memory 520. The processor 510 can be any custom made or commercially available processor, a central processing unit (CPU), an auxiliary processor among several processors associated with the computer 500, a semiconductor based microprocessor (in the form of a microchip or chip set), a macro processor, or generally any device for executing software instructions.

The memory 520 can include any one or combination of volatile memory elements and nonvolatile memory elements. Moreover, the memory 520 may incorporate electronic, magnetic, optical, and/or other types of storage media. Note that the memory 520 can have a distributed architecture, where various components are situated remote from one another, but can be accessed by the processor 510.

The software in memory 520 may include one or more separate programs, each of which comprises an ordered listing of executable instructions for implementing logical functions. In the example of FIG. 5, the software in the memory 520 includes the calculation module 130 in accordance with an exemplary embodiment, among other modules 120, 140, and a suitable operating system (O/S) 550. The operating system 550 essentially controls the execution of other computer programs, such as the calculation module 130, and provides scheduling, input-output control, file and data management, memory management, and communication control and related services.

The I/O devices 530 may include input devices, for example but not limited to, a keyboard, mouse, scanner, microphone, etc. Furthermore, the I/O devices A16 may also include output devices, for example but not limited to, a printer, display, etc. Finally, the I/O devices 530 may further include devices that communicate both inputs and outputs, for instance but not limited to, a modulator/demodulator (modem; for accessing another device, system, or network), a radio frequency (RF) or other transceiver, a telephonic interface, a bridge, a router, etc.

When the computer 500 is in operation, the processor 510 is configured to execute software stored within the memory 520, to communicate data to and from the memory 520, and to generally control operations of the computer 500 pursuant to the software. The calculation module 130 and the O/S 550, in whole or in part, but typically the latter, are read by the processor 510, perhaps buffered within the processor 510, and then executed.

Certain embodiments of the present disclosure can be implemented in hardware, software, firmware, or a combination thereof. For example, a module in software is a part of a software program, whereas a module in hardware is a self-contained component. Various embodiments of the present disclosure are implemented in software or firmware that is stored in a memory and that is executed by a suitable instruction execution system. If implemented in hardware, various embodiments can be implemented with any or a combination of the following technologies, which are all well known in the art: a discrete logic circuit(s) having logic gates for implementing logic functions upon data signals, an application specific integrated circuit (ASIC) having appropriate combinational logic gates, a programmable gate array(s) (PGA), a field programmable gate array (FPGA), etc.

In one embodiment, the flowchart of FIG. 4 and other disclosed processes comprise an ordered listing of executable instructions for implementing logical functions, and can be embodied in any computer-readable medium for use by or in connection with an instruction execution system, apparatus, or device, such as a computer-based system, processor-containing system, or other system that can fetch the instructions from the instruction execution system, apparatus, or device and execute the instructions. In the context of this document, a “computer-readable medium” can be any means that can contain, store, communicate, or transport the program for use by or in connection with the instruction execution system, apparatus, or device. The computer readable medium can be, for example but not limited to, an electronic, magnetic, optical, electromagnetic, infrared, or semiconductor system, apparatus, device, or propagation medium. More specific examples (a nonexhaustive list) of the computer-readable medium would include the following: an electrical connection (electronic) having one or more wires, a portable computer diskette (magnetic), a random access memory (RAM) (electronic), a read-only memory (ROM) (electronic), an erasable programmable read-only memory (EPROM or Flash memory) (electronic), an optical fiber (optical), and a portable compact disc read-only memory (CDROM) (optical).

Any process descriptions or blocks in flow charts should be understood as representing modules, segments, or portions of code which include one or more executable instructions for implementing specific logical functions or steps in the process, and alternate implementations are included within the scope of the disclosure in which functions may be executed out of order from that shown or discussed, including substantially concurrently or in reverse order, depending on the functionality involved, as would be understood by those reasonably skilled in the art of the present disclosure.

It should be emphasized that the above-described embodiments are merely possible examples of implementations, merely set forth for a clear understanding of the principles of the disclosure. Many variations and modifications may be made to the above-described embodiment(s) without departing substantially from the principles of the present disclosure. All such modifications and variations are intended to be included herein within the scope of this disclosure and protected by the following claims.

1. A system comprising:
a field measurement apparatus configured to acquire measurement data of a vector field corresponding to one dimension of the vector field, wherein the measurements acquired by the field measurement apparatus are limited to the one dimension of the vector field; and
at least one computing device having a processor and memory, the at least one computing device configured to simultaneously solve a set of equations characterizing the vector field by composing the set of equations into discrete counterparts, obtaining the measurement data of the vector field as input data for the discrete counterparts to the set of equations, and computing output data satisfying the discrete counterparts to the set of equations in at least one vector dimension that differs from the vector dimension of the input data using a matrices solution.

2. The system of claim 1, wherein the field measurement apparatus acquires the measurement data by scanning one or more field sensors, obtaining the data from an array of field sensors, or obtaining an optical image that is correlated with the vector field.

3. The system of claim 1, wherein the vector field comprises a magnetic field \vec{B}.

4. The system of claim 3, wherein the discrete counterparts to the set of equations comprise:
$${B}_{y} ( i , j , k + 1 ) - {B}_{y} ( i , j , k - 1 ) = \frac{2 Δ xy}{Δ {z}_{1} + Δ {z}_{2}} ( {B}_{z} ( i , j + 1 , k ) - {B}_{z} ( i , j - 1 , k ) )$$
$${B}_{x} ( i , j , k + 1 ) - {B}_{x} ( i , j , k - 1 ) = \frac{2 Δ xy}{Δ {z}_{1} + Δ {z}_{2}} ( {B}_{z} ( i + 1 , j , k ) - {B}_{z} ( i - 1 , j , k ) )$$
$${B}_{x} ( i , j + 1 , k ) - {B}_{x} ( i , j - 1 , k ) + {B}_{y} ( i + 1 , j , k ) - {B}_{y} ( i - 1 , j , k ) = 0$$
$$\frac{{B}_{x} ( i + 1 , j , k ) - {B}_{x} ( i - 1 , j , k )}{2 Δ xy} + \frac{{B}_{y} ( i , j + 1 , k ) - {B}_{y} ( i , j - 1 , k )}{2 Δ xy} = - \frac{{B}_{z} ( i , j , k + 1 ) - {B}_{z} ( i , j , k - 1 )}{Δ {z}_{1} + Δ {z}_{2}} .$$

5. The system of claim 1, wherein the field measurement apparatus comprises a magneto-optical indicator film (MOIF).

6. The system of claim 1, wherein the vector field comprises an electric field.

7. The system of claim 1, wherein the vector field comprises a fluidic flow field.

8. The system of claim 1, wherein the vector field (\vec{A}) satisfies ∇·\vec{A}=0 and ∇×\vec{A}=0 for at least a set condition.

9. The system of claim 1, further comprising a mapping module configured to construct a three dimensional map of the vector field from the measurement data and the output data.

10. A method comprising:
obtaining, by at least one computing device, a set of equations for a multidimensional vector field;
composing the set of equations into discrete counterparts;
obtaining, by the at least one computing device, measurement data for one dimension of the vector field, wherein the measurement data is limited to the one dimension of the vector field;
calculating, by the at least one computing device, output data along remaining dimensions of the vector field by simultaneously solving, using a matrices solution, the discrete counterparts to the set of equations using the measurement data as input data; and
constructing, by the at least one computing device, a three-dimensional model of the multidimensional vector field from the measurement data and the output data.

11. The method of claim 10, wherein the discrete counterparts to the set of equations comprise:
$${B}_{y} ( i , j , k + 1 ) - {B}_{y} ( i , j , k - 1 ) = \frac{2 Δ xy}{Δ {z}_{1} + Δ {z}_{2}} ( {B}_{z} ( i , j + 1 , k ) - {B}_{z} ( i , j - 1 , k ) )$$
$${B}_{x} ( i , j , k + 1 ) - {B}_{x} ( i , j , k - 1 ) = \frac{2 Δ xy}{Δ {z}_{1} + Δ {z}_{2}} ( {B}_{z} ( i + 1 , j , k ) - {B}_{z} ( i - 1 , j , k ) )$$
$${B}_{x} ( i , j + 1 , k ) - {B}_{x} ( i , j - 1 , k ) + {B}_{y} ( i + 1 , j , k ) - {B}_{y} ( i - 1 , j , k ) = 0$$
$$\frac{{B}_{x} ( i + 1 , j , k ) - {B}_{x} ( i - 1 , j , k )}{2 Δ xy} + \frac{{B}_{y} ( i , j + 1 , k ) - {B}_{y} ( i , j - 1 , k )}{2 Δ xy} = - \frac{{B}_{z} ( i , j , k + 1 ) - {B}_{z} ( i , j , k - 1 )}{Δ {z}_{1} + Δ {z}_{2}} .$$

12. The method of claim 10, wherein the measurement data is acquired by scanning one or more field sensors, obtaining the data from an array of field sensors, or obtaining an optical image that is correlated with the vector field.

13. The method of claim 10, wherein the measurement data comprises a plurality of slices along increasing heights of a single component of the vector field.

14. The method of claim 10, wherein the vector field comprises a magnetic field, a fluidic flow field, or an electric field.

15. The method of claim 14, wherein the vector field (\vec{A}) satisfies ∇·\vec{A}=0 and ∇×\vec{A}=0 for at least a set condition.

16. The method of claim 10, further comprising positively validating a theoretical model of the vector field against the constructed model of the vector field without applying an error correction process to the constructed model.

17. A non-transitory computer readable medium storing a plurality of computer instructions that, when executed by at least one computing device, cause the at least one computing device to at least:
obtain a set of equations for a multidimensional vector field;
obtain measurement data for one dimension of the vector field, wherein the measurement data is limited to the one dimension of the vector field;
calculate output data corresponding to remaining dimensions of the vector field by simultaneously solving the set of equations using the measurement data; and
construct a three-dimensional map of the multidimensional vector field from the measurement data and the output data.

18. The system of claim 3, wherein the magneto-optical indicator film determines a z component of a stay magnetic field from a magnetic structure.

19. The non-transitory computer readable medium of claim 17, wherein the measurement data comprises a plurality of slices along increasing heights of a single component of the vector field.

20. The non-transitory computer readable medium of claim 17, wherein the vector field comprises a magnetic field, a fluidic flow field, or an electric field.
